(19) United States
(12) Patent Application Publication
(10) Pub. No.: US 2014/0073177 A1
(43) Pub. Date: Mar. 13, 2014

(54) DIP SOCKET

(71) Applicant: SAMSUNG ELECTRO-MECHANICS CO., LTD., Suwon (KR)

(72) Inventor: Kang Hyun Lee, Suwon (KR)

(73) Assignee: SAMSUNG ELECTRO-MECHANICS CO., LTD., Suwon (KR)

(21) Appl. No.: 13/757,579

(22) Filed: Feb. 1, 2013

(30) Foreign Application Priority Data
Sep. 11, 2012 (KR) 10-2012-0100561

(51) Int. Cl. H05K 7/10

(52) U.S. Cl. CPC H05K 7/103
USPC 439/525

(57) ABSTRACT

Disclosed herein is a dip socket, including: a first pin connecting part and a second pin connecting part provided by forming a plurality of connecting members connected with a plurality of pins of a dip module in a line, respectively; and a width controlling means provided between the first pin connecting part and the second pin connecting part and configured to control a width between the first pin connecting part and the second pin connecting part.

### CROSS REFERENCE TO RELATED APPLICATION

This application claims the benefit of Korean Patent Application No. 10-2012-0100561, filed on Sep. 11, 2012, entitled “Dip Socket”, which is hereby incorporated by reference in its entirety into this application.

### BACKGROUND OF THE INVENTION

1. Technical Field

The present invention relates to a dip socket.

2. Description of the Related Art

A package module passes through multi-functioning, small-sizing, and coupling processes in order to respond to the demand of a market, and as a result, various shapes of modules have been developed. In addition, sockets determined subordinately according to a shape of the package module have required a new design in order to evaluate the various shapes of modules.

Among the sockets, a dip socket targeting a dual in-line package (DIP) type module is installed and fixed to a printed circuit board (PCB) with a pattern and then the dip module is inserted into the dip socket to evaluate the package through an electric contact of a pin fixed to the dip socket and a lead of the package.

Further, as those disclosed in Japanese Utility Model Laid-Open Publication No. 1993-001247, in a known dip socket, since pins are fixed to the dip socket with a predetermined pin distance and a predetermined line width, in the case of the dip module of which a pin distance or a line width is not regular, there is a problem in that a new dip socket needs to be designed and manufactured according to a shape of the dip module.

### SUMMARY OF THE INVENTION

The present invention has been made in an effort to provide a dip socket capable of controlling a distance between connecting portions of the dip socket to which pins are connected according to a distance between the pins of a dip module.

Further, the present invention has been made in an effort to provide a dip socket capable of controlling a width between connecting portions of the dip socket to which pins are connected according to a width between pin lines of a dip module.

According to a first preferred embodiment of the present invention, there is provided a dip socket, including: a first pin connecting part and a second pin connecting part provided by forming a plurality of connecting members connected with a plurality of pins of a dip module in a line, respectively; and a width controlling means provided between the first pin connecting part and the second pin connecting part and configured to control a width between the first pin connecting part and the second pin connecting part.

The width controlling means may include a guide frame provided at the side of the first pin connecting part; and a slide frame provided at the side of the second pin connecting part so as to face the guide frame and be coupled with the guide frame, the slide frame being slid along the guide frame to control the width between the first pin connecting part and the second pin connecting part.

The width controlling means may further include a fixing member fixing the guide frame and the slide frame to each other.

The guide frame may have a screw hole penetrating through the inside and the outside, and the fixing member may be formed of a screw, the screw being coupled with the screw hole to fix the slide frame.

The first pin connecting part and the second pin connecting part may include distance controlling means controlling a distance between the plurality of connecting members so as to correspond to a distance between a plurality of pins of the dip module.

The distance controlling means may include a first guide frame and a second guide frame positioned at the first pin connecting part and the second pin connecting part, respectively; and a plurality of pin blocks installed on the first guide frame and the second guide frame in a line, respectively and having the plurality of connecting members, respectively, the plurality of pin blocks being guided and moved by the first guide frame and the second guide frame, respectively to control the distance between the plurality of connecting members.

The distance controlling means may further include pin block fixing means fixing the plurality of pin blocks.

The pin block fixing means may include a plurality of first magnets installed on the sides of the plurality of pin blocks, respectively; and a plurality of second magnets positioned at the outsides of the first guide frame and the second guide frame and fixed detachably to the plurality of first magnets by a magnetic force.

The first guide frame and the second guide frame may have inserting holes penetrating through the inside and the outside at one side thereof, respectively, and the pin block may have a connecting groove which is opened to one side so as to be coupled with the insert hole and has the connecting member.

According to a second preferred embodiment of the present invention, there is provided a dip socket, including: a first pin connecting part and a second connecting part provided by forming a plurality of connecting members connected with a plurality of pins of a dip module in a line, respectively; and a support part disposed at both sides of the first pin connecting part and the second connecting part to support the first pin connecting part and the second connecting part, in which the first pin connecting part and the second connecting part include distance controlling means controlling a distance between the plurality of connecting members so as to correspond to a distance between a plurality of pins of the dip module.

The distance controlling means may include a first guide frame and a second guide frame positioned at the first pin connecting part and the second pin connecting part, respectively; and a plurality of pin blocks installed on the first guide frame and the second guide frame in a line, respectively and having the plurality of connecting members, respectively, the plurality of pin blocks being guided and moved by the first guide frame and the second guide frame, respectively to control the distance between the plurality of connecting members.

The distance controlling means may further include pin block fixing means fixing the plurality of pin blocks.

The pin block fixing means may include first magnets installed on the sides of the pin blocks; and second magnets positioned at the outsides of the first guide frame and the second guide frame and detachably fixed to the plurality of first magnets by a magnetic force.

The first guide frame and the second guide frame may have inserting holes penetrating through the inside and the outside at one side thereof, and the pin block may have a connecting groove which is opened to one side so as to be coupled with the insert hole and has the connecting member.

The dip socket may further include a width controlling means provided between the first pin connecting part and the second connecting part and controlling a width between the first pin connecting part and the second connecting part.

The width controlling means may include a guide frame provided at the side of the first pin connecting part; and a slide frame provided at the side of the second pin connecting part so as to face the guide frame and be coupled with the guide frame, the slide frame being slid along the guide frame to control the width between the first pin connecting part and the second connecting part.

The width controlling means may further include a fixing member fixing the guide frame and the slide frame to each other.

The guide frame may have a screw hole penetrating through the inside and the outside, and the fixing member may be formed of a screw, the screw being coupled with the screw hole to fix the slide frame.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a use state diagram illustrating a dip socket according to an exemplary embodiment of the present invention;

FIG. 2 is a perspective view illustrating the dip socket according to the exemplary embodiment of the present invention;

FIG. 3 is a cross-sectional view illustrating a state before widths of a first pin connecting part and a second pin connection part are controlled by a width controlling means in the dip socket according to the exemplary embodiment of the present invention;

FIG. 4 is a cross-sectional view illustrating a state after widths of a first pin connecting part and a second pin connection part are controlled by a width controlling means in the dip socket according to the exemplary embodiment of the present invention;

FIG. 5 is a conceptual diagram illustrating a pin connecting part in the dip socket according to the exemplary embodiment of the present invention;

FIG. 6 is a cross-sectional view illustrating a state before a pin block of a first pin connecting part is fixed in the dip socket according to the exemplary embodiment of the present invention;

FIG. 7 is a cross-sectional view illustrating a state after a pin block of a first pin connecting part is fixed in the dip socket according to the exemplary embodiment of the present invention; and

FIG. 8 is a cross-sectional view illustrating a second pin connecting part in the dip socket according to the exemplary embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

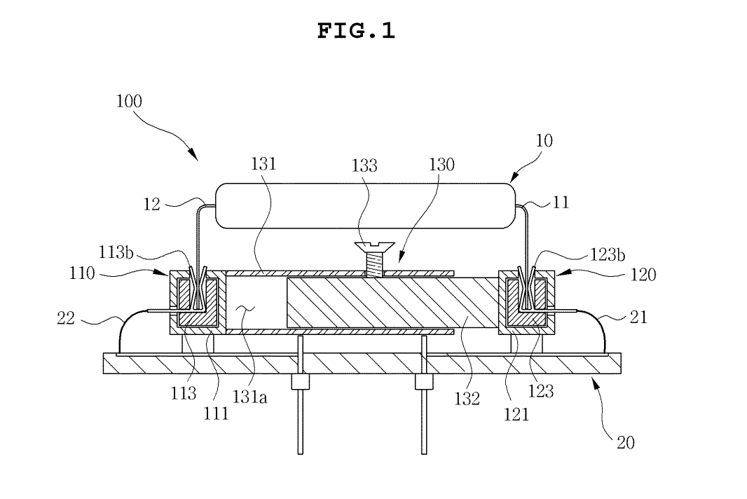

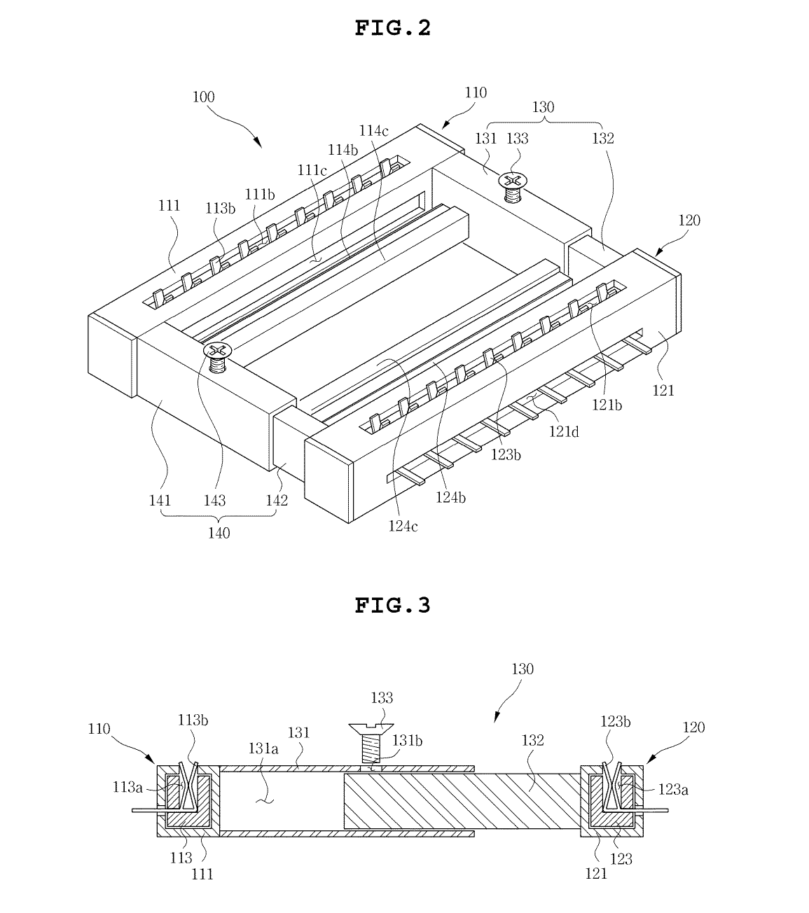

FIG. 1 is a use state diagram illustrating a dip socket according to an exemplary embodiment of the present invention, and FIG. 2 is a perspective view illustrating the dip socket according to the exemplary embodiment of the present invention.

Referring to FIGS. 1 and 2, a dip socket 100 according to an exemplary embodiment of the present invention includes a first pin connecting part 110, a second pin connecting part 120, and width controlling means (support parts) 130 and 140. Here, the first pin connecting part 110 and the second pin connecting part 120 include distance controlling means, respectively.

Hereinafter, the dip socket 100 according to the exemplary embodiment of the present invention will be described in more detail with reference to FIGS. 1 to 8.

Referring to FIGS. 1 and 2, the first pin connecting part 110 and the second pin connecting part 120 are provided so that a plurality of connecting members 113b and 123b, which are connecting portions connected with a plurality of pins 11 and 12 of a dip module 10, are formed in a line, respectively. In this case, the first pin connecting part 110 and the second pin connecting part 120 may be positioned to be spaced apart from each other with a predetermined distance in a parallel direction.

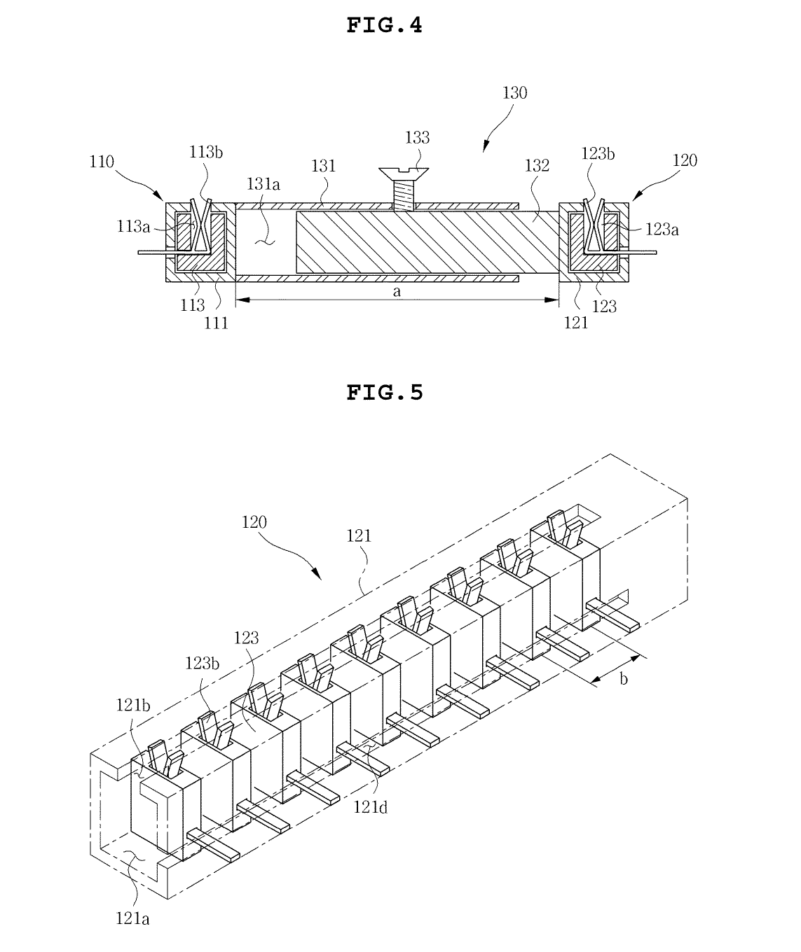

FIG. 3 is a cross-sectional view illustrating a state before widths of first and second pin connecting parts are controlled by a width controlling means in the dip socket according to the exemplary embodiment of the present invention, and FIG. 4 is a cross-sectional view illustrating a state after widths of first and second pin connecting parts are controlled by a width controlling means in the dip socket according to the exemplary embodiment of the present invention.

Referring to FIGS. 2 to 4, the width controlling means 130 and 140 which are the support parts are disposed at both sides of the first pin connecting part 110 and the second pin connecting part 120 to support the first pin connecting part 110 and the second pin connecting part 120. In this case, a pair of width controlling means 130 and 140 is provided between the first pin connecting part 110 and the second pin connecting part 120 in parallel to control a width a between the first pin connecting part 110 and the second pin connecting part 120.

Herein, the width controlling means 130 and 140 include guide frames 131 and 141, and slide frames 132 and 142 which are guided by the guide frames 131 and 141 and slid. In addition, the width controlling means 130 and 140 may further include fixing members 133 and 143.

Further, the guide frames 131 and 141 are formed at the side of the first pin connecting part 110, and the slide frames 132 and 142 are formed at the side of the second pin connecting part 120.

Here, the guide frames 131 and 141 and the slide frames 132 and 142 are formed to extend in a facing direction, and the slide frames 132 and 142 and the guide frames 131 and 141 are moved in the facing direction.

In this case, sides of the slide frames 132 and 142 are inserted into the guide frames 131 and 141, and outer surfaces of the sides of the slide frames 132 and 142 are slid along inner surfaces of the guide frames 131 and 141.

In addition, the guide frames 131 and 141 may be formed in a tube shape in which a guide hole 131a is formed in a longitudinal direction, and the slide frames 132 and 142 may be formed in a corresponding shape to the guide hole 131a of the guide frames 131 and 141.

In this case, the guide frames 131 and 141 may be formed in a quadrangular tube shape, but the present invention is not necessarily limited thereto and for example, the guide frames 131 and 141 may be formed in various shapes including a circular tube shape. Further, the slide frames 132 and 142 may be formed in a quadrangular tube or quadrangular column shape, but the present invention is not limited thereto.

The fixing members 133 and 143 may fix the guide frames 131 and 141 and the slide frames 132 and 142 to each other. Here, the fixing members 133 and 143 are formed of screws, and screw holes 131b penetrating through inside and outside of the guide frames 131 and 141 are formed and the screws are coupled with the screw holes 131b to fix the slide frames 132 and 142. In this case, when the screws are coupled with the screw holes 131b, ends of the screws are in contact with outer surfaces of the slide frames 132 and 142 to fix the slide frames 132 and 142 without moving.

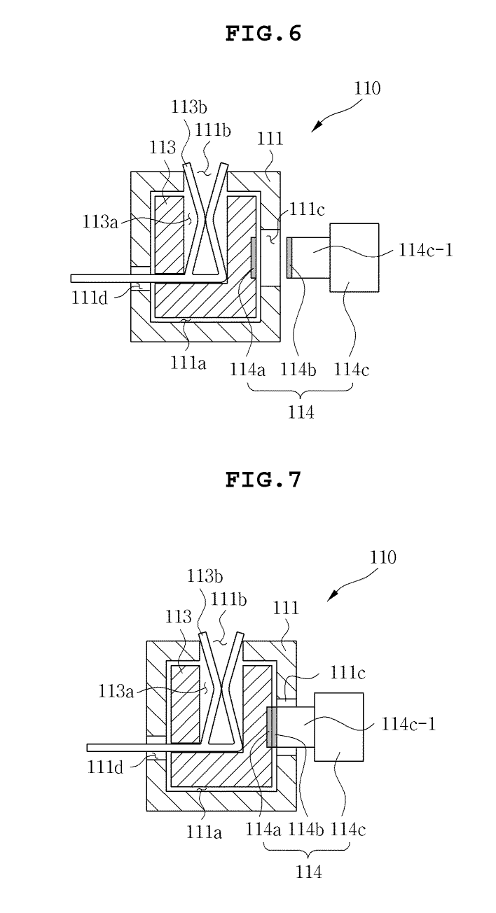

FIG. 5 is a conceptual diagram illustrating a pin connecting part in the dip socket according to the exemplary embodiment of the present invention, and FIG. 6 is a cross-sectional view illustrating a state before a pin block of a first pin connecting part is fixed in the dip socket according to the exemplary embodiment of the present invention.

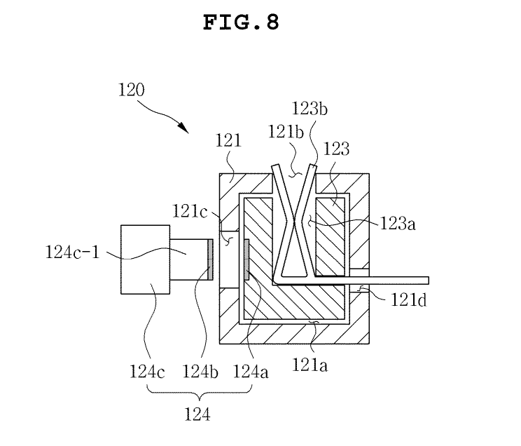

FIG. 7 is a cross-sectional view illustrating a state after a pin block of a first pin connecting part is fixed in the dip socket according to the exemplary embodiment of the present invention, and FIG. 8 is a cross-sectional view illustrating a second pin connecting part in the dip socket according to the exemplary embodiment of the present invention.

Referring to FIGS. 1 to 5, the distance controlling means may control a distance b between the plurality of connecting members 113b and 123b according to a distance b between the plurality of pins 11 and 12 of the dip module 10.

Here, the distance controlling means may include a first guide frame 111, a second guide frame 121, and pin blocks 113 and 123.

Further, referring to FIGS. 5, 6, and 8, the distance controlling means may further include pin block fixing means 114 and 124 fixing the pin blocks 113 and 123.

First, the first guide frame 111 and the second guide frame 121 may be formed in tube shapes with guide holes 111a and 121a in longitudinal directions of the first guide frame 111 and the second guide frame 121 therein.

Further, the first guide frame 111 and the second guide frame 121 may be formed in quadrangular tube shapes, but the present invention is not necessarily limited thereto and for example, the first guide frame 111 and the second guide frame 121 may be formed in various shapes including a circular tube shape.

Further, inserting holes 111b and 121b penetrating through the inside and outside may be formed at the centers of the upper portions of the first guide frame 111 and the second guide frame 121 in the longitudinal directions of the first guide frame 111 and the second guide frame 121.

The pin blocks 113 and 123 are provided in plural and installed on the first guide frame 111 and the second guide frame 121 in a line, respectively and include a plurality of connecting members 113b and 123b, respectively.

Here, the pin blocks 113 and 123 are positioned in the guide holes 111a and 121a of the first guide frame 111 and the second guide frame 121 to be guided and moved by the guide holes 111a and 121a.

Further, the pin blocks 113 and 123 include connecting grooves 113a and 123a opened upwards and the connecting members 113b and 123b installed on the connecting grooves 113a and 123a. In this case, the pins 11 and 12 of the dip module 10 are inserted to the connecting grooves 113a and 123a and may be connected to the connecting members 113b and 123b.

In addition, referring to FIGS. 1 and 2, sides of the connecting members 113b and 123b are positioned in the connecting grooves 113a and 123a, and the other sides thereof penetrate through the pin blocks 113 and 123 and protrude from both sides of the first guide frame 111 and the second guide frame 121 to be connected with an external terminal 20. Here, the other sides of the connecting members 113b and 123b may be connected with, for example, lead wires 21 and 22 of the external terminal 20.

Further, referring to FIGS. 2, 6, and 8, movement holes 111d and 121d are formed at both sides of the first guide frame 111 and the second guide frame 121, and the connecting members 113b and 123b may protruding from the both side of the first guide frame 111 and the second guide frame 121 through the movement holes 111d and 121d. Accordingly, the connecting members 113b and 123b may be moved through the movement holes 111d and 121d, and as a result, the pin blocks 113 and 123 may be easy to move.

Further, sides of the connecting members 113b and 123b protrude upward the pin blocks 113 and 123 and thus the protruding portions of the connecting members 113b and 123b may be moved along the inserting holes 111b and 121b formed at the upper side of the first guide frame 111 and the second guide frame 121.

Meanwhile, the sides of the connecting members 113b and 123b are formed to cross each other to be easily connected with the plurality of pins 11 and 12 of the dip module 10. In this case, the sides of the connecting members 113b and 123b may be formed, for example, in an “X”-lettered shape, but the present invention is not limited thereto.

In addition, the connecting members 113b and 123b may be formed of, for example, wires, but the present invention is not limited thereto.

Referring to FIGS. 2, 6, and 8, the pin block fixing members 114 and 124 include, for example, first magnets 114a and 124a and second magnets 114b and 124b to fix the plurality of pin blocks 113 and 123.

Here, the magnets 114a and 124a are provided in plural to be installed on the sides of the plurality of pin blocks 113 and 123, respectively, and the second magnets 114b and 124b are positioned at the outsides of the first guide frame 111 and the second guide frame 121, and as a result, the first magnets 114a and 124a and the second magnets 114b and 124b are detachably fixed to each other by a magnetic force to fix the pin blocks 113 and 123.

In this case, when the second magnets 114b and 124b deviate from first magnets 114a and 124a while the pin blocks 113 and 123 move, the coupling between the first magnets 114a and 124a and the second magnets 114b and 124b due to the magnetic force is released and thus the pin blocks 113 and 123 are movable. Further, when the second magnets 114b and 124b are moved in first magnets 114a and 124a directions after the pin blocks 113 and 123 are moved to fix the first magnets 114a and 124a and the second magnets 114b and 124b to each other by the magnetic force generated therebetween. Accordingly, the pin blocks 113 and 123 with the first magnets 114a and 124a are fixed to the second magnets 114b and 124b to fix the distance between the plurality of pin blocks 113 and 123 with the connecting members 113 and 123.

Further, the first magnets 114a and 124a and the second magnets 114b and 124b may be made of permanent magnets, but the present invention is not limited thereto.

In addition, the second magnets 114b and 124b may be positioned at the outer sides of the first guide frame 111 and the second guide frame 121 in bar shapes. In addition, the second magnets 114b and 124b are in plural to be positioned outside in the longitudinal directions of the first guide frame 111 and the second guide frame 121, respectively.

Further, fixing holes 111c and 121c may be formed at the side of a facing direction of the first guide frame 111 and the second guide frame 121. Here, the fixing holes 111c and 121c may be formed in the longitudinal directions of the first guide frame 111 and the second guide frame 121.

In this case, the first magnets 114a and 124a are installed on the pin block 113 and 123 in the fixing holes 111c and 121c directions, and the second magnets 114b and 124b are inserted into the sides of the fixing holes 111c and 121c, and as a result, the coupling force between the first magnets 114a and 124a and the second magnets 114b and 124b due to the magnetic force may be increased.

Further, the second magnets 114b and 124b are installed on support parts 114c and 124c to be supported by the support parts 114c and 124c. Accordingly, a user holds the support parts 114c and 124c to easily detach the second magnets 114b and 124b installed on the support parts 114c and 124c from the first magnets 114a and 124a.

Further, the support parts 114c and 124c are made of non-magnetic materials to prevent the magnetic force of the first magnets 114a and 124a from being applied to the outside of the dip module 100 of the present invention, but the materials of the support parts 114c and 124c of the present invention are not necessarily limited thereto.

In addition, the support parts 114c and 124c may include protruding parts 114c-1 and 124c-1 of which sides protrude in a form corresponding to the fixing holes 111c and 121c so as to be inserted into the fixing holes 111c and 121c. In this case, the second magnets 114b and 124b are attached to ends of the protruding parts to be easily coupled with the first magnets 114a and 124a through the fixing holes 111c and 121c.

However, the pin block fixing members 114 and 124 of the present invention are not limited to an example of including the first magnets 114a and 124a and the second magnets 114b and 124b, but as another example, the pin block fixing members 114 and 124 are formed of a plurality of fixing screws, fixing screw holes (not shown) are formed in the first guide frame 111 and the second guide frame 121, and the fixing screws may be coupled with the fixing screw holes. As a result, the fixing screws are in contact with the pin blocks 113 and 123 to fix the plurality of pin blocks 113 and 123.

According to the embodiments of the present invention, a dip socket may be coupled with dip modules having various shapes regardless of a pin distance of the dip module by controlling a distance between connecting portions of the dip socket connected with the pin of the dip module, such that it is possible to reduce manufacturing cost.

Further, according to the embodiments of the present invention, a dip socket may be coupled with dip modules having various shapes regardless of a width between pin lines of the dip module by controlling a width between connecting portions of the dip socket connected with the pin of the dip module, such that it is possible to reduce manufacturing cost.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A dip socket, comprising:
a first pin connecting part and a second pin connecting part provided by forming a plurality of connecting members connected with a plurality of pins of a dip module in a line, respectively; and
a width controlling means provided between the first pin connecting part and the second pin connecting part and configured to control a width between the first pin connecting part and the second connecting part.

2. The dip socket as set forth in claim 1, wherein the width controlling means includes:
a guide frame provided at the side of the first pin connecting part; and
a slide frame provided at the side of the second pin connecting part so as to face the guide frame and be coupled with the guide frame,
the slide frame being slid along the guide frame to control the width between the first pin connecting part and the second pin connecting part.

3. The dip socket as set forth in claim 2, wherein the width controlling means further includes a fixing member fixing the guide frame and the slide frame to each other.

4. The dip socket as set forth in claim 3, wherein the guide frame has a screw hole penetrating through the inside and the outside, and
the fixing member is formed of a screw,
the screw being coupled with the screw hole to fix the slide frame.

5. The dip socket as set forth in claim 1, wherein the first pin connecting part and the second pin connecting part include distance controlling means controlling a distance between the plurality of connecting members so as to correspond to a distance between a plurality of pins of the dip module.

6. The dip socket as set forth in claim 5, wherein the distance controlling means includes:
a first guide frame and a second guide frame positioned at the first pin connecting part and the second pin connecting part, respectively; and
a plurality of pin blocks installed on the first guide frame and the second guide frame in a line, respectively and having the plurality of connecting members, respectively,
the plurality of pin blocks being guided and moved by the first guide frame and the second guide frame, respectively to control the distance between the plurality of connecting members.

7. The dip socket as set forth in claim 6, wherein the distance controlling means further includes pin block fixing means fixing the plurality of pin blocks.

8. The dip socket as set forth in claim 7, wherein the pin block fixing means includes:
a plurality of first magnets installed on the sides of the plurality of pin blocks, respectively; and
a plurality of second magnets positioned at the outsides of the first guide frame and the second guide frame and fixed detachably to the plurality of first magnets by a magnetic force.

9. The dip socket as set forth in claim 6, wherein the first guide frame and the second guide frame have inserting holes penetrating through the inside and the outside at one side thereof; and
the pin block has a connecting groove which is opened to one side so as to be coupled with the insert hole and has the connecting member.

10. A dip socket, comprising:
a first pin connecting part and a second pin connecting part provided by forming a plurality of connecting members connected with a plurality of pins of a dip module in a line, respectively; and
support parts disposed at both sides of the first pin connecting part and the second connecting part to support the first pin connecting part and the second connecting part,
wherein the first pin connecting part and the second connecting part include distance controlling means controlling a distance between the plurality of connecting members so as to correspond to a distance between a plurality of pins of the dip module.

11. The dip socket as set forth in claim 10, wherein the distance controlling means includes:
a first guide frame and a second guide frame positioned at the first pin connecting part and the second pin connecting part, respectively; and
a plurality of pin blocks installed on the first guide frame and the second guide frame in a line, respectively and having the plurality of connecting members, respectively,
the plurality of pin blocks being guided and moved by the first guide frame and the second guide frame, respectively to control the distance between the plurality of connecting members.

12. The dip socket as set forth in claim 11, wherein the width controlling means further includes pin block fixing means fixing the plurality of pin blocks.

13. The dip socket as set forth in claim 12, wherein the pin block fixing means includes:
first magnets installed on the sides of the pin blocks; and
second magnets positioned at the outsides of the first guide frame and the second guide frames and detachably fixed to the plurality of first magnets by a magnetic force.

14. The dip socket as set forth in claim 11, wherein the first guide frame and the second guide frame have inserting holes penetrating through the inside and the outside at one side thereof, and
the pin block has a connecting groove which is opened to one side so as to be coupled with the insert hole and has the connecting member.

15. The dip socket as set forth in claim 10, wherein the support part is formed of a width controlling means provided between the first pin connecting part and the second pin connecting part and controlling a width between the first pin connecting part and the second connecting part.

16. The dip socket as set forth in claim 15, wherein the width controlling means further includes:
a guide frame provided at the side of the first pin connecting part; and
a slide frame provided at the side of the second pin connecting part so as to face the guide frame and be coupled with the guide frame,
the slide frame being slid along the guide frame to control the width between the first pin connecting part and the second pin connecting part.

17. The dip socket as set forth in claim 16, wherein the width controlling means further includes a fixing member fixing the guide frame and the slide frame to each other.

18. The dip socket as set forth in claim 17, wherein the guide frame has a screw hole penetrating through the inside and the outside, and
the fixing member is formed of a screw,
the screw being coupled with the screw hole to fix the slide frame.
